(19) United States
(12) Patent Application Publication
(10) Pub. No.: US 2025/0267884 A1
(43) Pub. Date: Aug. 21, 2025

(54) SEMICONDUCTOR DEVICE

(71) Applicant: Mitsubishi Electric Corporation, Tokyo (JP)

(72) Inventors: Takahiro NAKATANI, Tokyo (JP); Kenji HARADA, Tokyo (JP); Kosuke SAKAGUCHI, Tokyo (JP); Reona FURUKAWA, Tokyo (JP)

(73) Assignee: Mitsubishi Electric Corporation, Tokyo (JP)

(21) Appl. No.: 18/955,910

(22) Filed: Nov. 21, 2024

(30) Foreign Application Priority Data
Feb. 21, 2024 (JP) 2024-024338

(51) Int. Cl. H01L 29/739; H01L 29/06; H01L 29/423

(52) U.S. Cl. CPC H10D 12/481; H10D 62/127; H10D 64/513

(57) ABSTRACT

A semiconductor device includes: a plurality of first active trench gates extending in a first direction and facing a source layer and a base layer via a trench-gate insulating film; and a second active trench gate extending in a second direction that intersects the first direction and connecting the adjacent first active trench gates to each other. A gate wiring electrode is connected to a wide portion in the first active trench gate. The second active trench gate is disposed below the gate wiring electrode. A connection portion between the first active trench gate and the second active trench gate is T-shaped in plan view.

### BACKGROUND OF THE INVENTION

### Field of the Invention

The present disclosure relates to a semiconductor device, and particularly relates to a semiconductor device including a trench-gate semiconductor element.

### Description of the Background Art

A semiconductor device including a trench-gate semiconductor element with a gate electrode embedded in a trench (hereinafter referred to as a “trench gate”) is known. For example, in a semiconductor device including a trench-gate insulated gate bipolar transistor (IGBT), a gate drive signal for driving the IGBT is input to a gate pad provided on the upper surface of the semiconductor device, passes through a gate wiring electrode, and is supplied to a plurality of trench gates.

Usually, the plurality of trench gates extend in a certain direction, and are arranged side by side at regular intervals in a direction intersecting the direction of the extension. The gate wiring electrode is connected to all trench gates to which gate drive signals are to be supplied (hereinafter referred to as “active trench gates”). Therefore, when a void occurs in a connection portion between the gate wiring electrode and a part of the active trench gate, the part of the active trench gate is insulated from the gate wiring electrode, and the IGBT partially stops operating. As a technique for solving this problem, Japanese Patent Application Laid-Open No. 2005-235913 discloses a structure provided with a coupling trench gate that connects adjacent active trench gates.

In the technique of Japanese Patent Application Laid-Open No. 2005-235913, there is a problem in that the trench becomes locally deeper at the intersection between the active trench gate and the coupling trench gate, leading to deteriorated embeddability of the gate electrode at that portion.

### SUMMARY

An object of the present disclosure is to provide a semiconductor device capable of preventing the generation of an active trench gate that is insulated from a gate wiring electrode while minimizing deterioration in the embeddability of a gate electrode.

A semiconductor device according to the present disclosure includes: a semiconductor substrate; an emitter electrode and a gate wiring electrode provided on an upper surface of the semiconductor substrate; a source layer of a first conductivity type disposed on a surface portion on the upper surface side of the semiconductor substrate and connected to the emitter electrode; a base layer of a second conductivity type disposed below the source layer; a collector electrode provided on a lower surface of the semiconductor substrate; a plurality of first active trench gates extending in a first direction and facing the source layer and the base layer via a trench-gate insulating film; and a second active trench gate extending in a second direction that intersects the first direction and connecting the adjacent first active trench gates to each other. Each of a plurality of the first active trench gates includes a portion that is wider than other portions. The gate wiring electrode extends in the second direction and is connected to the wider portion in each of a plurality of the first active trench gates. The second active trench gate is disposed below the gate wiring electrode. A connection portion between the first active trench gate and the second active trench gate is T-shaped in plan view.

According to the semiconductor device of the present disclosure, it is possible to prevent the generation of an active trench gate that is insulated from the gate wiring electrode while minimizing deterioration in the embeddability of the gate electrode.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a semiconductor device according to a first preferred embodiment;

FIG. 2 is a cross-sectional view taken along line A-A in FIG. 1;

FIG. 3 is a cross-sectional view taken along line B-B in FIG. 1;

FIG. 4 is a cross-sectional view taken along line C-C in FIG. 1;

FIG. 5 is a plan view of a semiconductor device according to a second preferred embodiment;

FIG. 6 is a plan view of a semiconductor device according to a third preferred embodiment;

FIG. 7 is a plan view of a semiconductor device according to a fourth preferred embodiment;

FIG. 8 is a cross-sectional view taken along line D-D in FIG. 7;

FIG. 9 is a cross-sectional view taken along line E-E in FIG. 7; and

FIG. 10 is a cross-sectional view taken along line F-F in FIG. 7.

### DESCRIPTION OF THE PREFERRED EMBODIMENTS

In the following preferred embodiment, the first conductivity type is described as an n-type and the second conductivity type is described as a p-type, but conversely, the first conductivity type may be a p-type and the second conductivity type may be an n-type. In addition, an n-type with a relatively high impurity concentration is referred to as “n⁺”, an n-type with a relatively low impurity concentration as “n⁻”, an n-type with a relatively high impurity concentration as “p⁺”, and a p-type with a relatively low impurity concentration as “p⁻”. Here, the height of the impurity concentration in each region is defined by the peak concentration. That is, a region with a high (or low) impurity concentration means a region with a high (or low) impurity peak concentration.

### First Preferred Embodiment

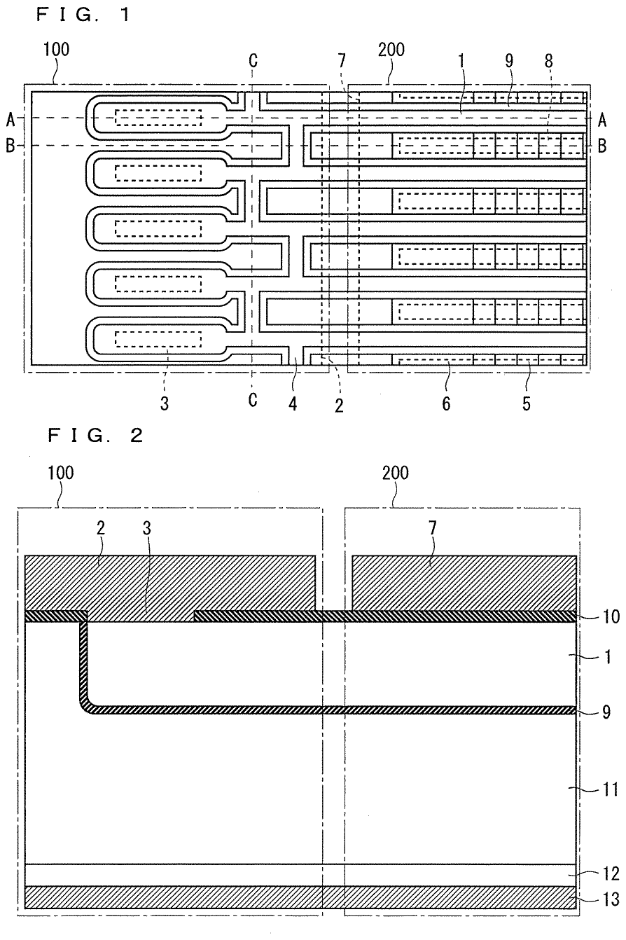

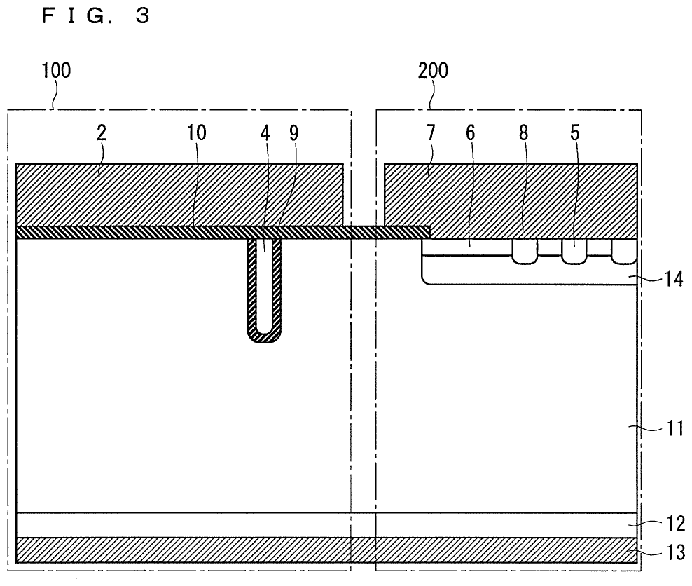

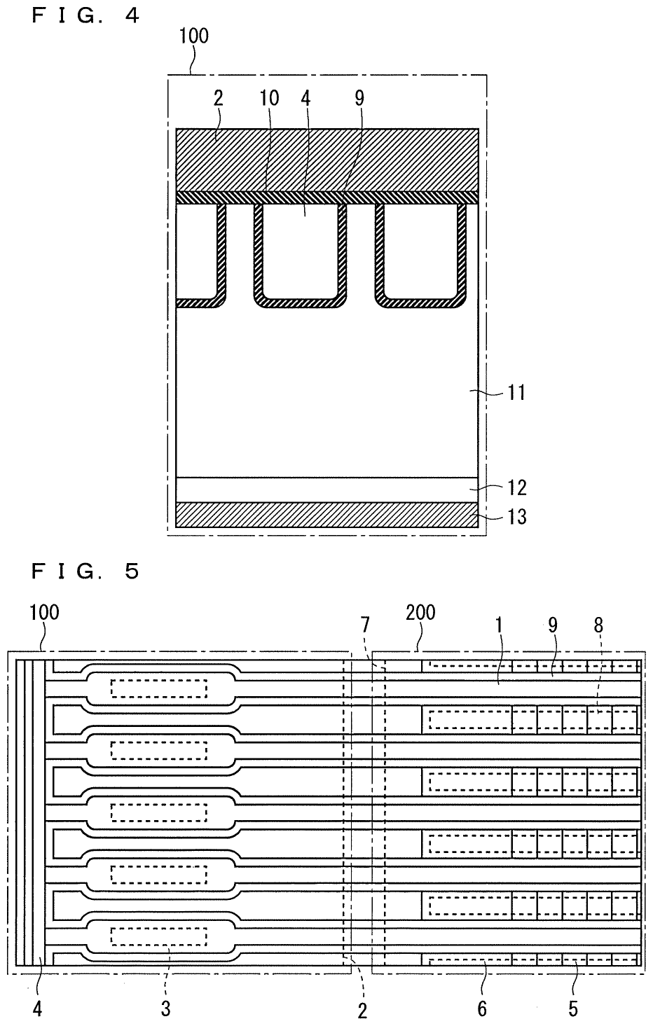

FIGS. 1 to 4 are diagrams illustrating a configuration of a semiconductor device according to a first preferred embodiment. FIG. 1 is a plan view of the semiconductor device. FIG. 2 is a cross-sectional view taken along line A-A in FIG. 1. FIG. 3 is a cross-sectional view taken along line B-B in FIG. 1. FIG. 4 is a cross-sectional view taken along line C-C in FIG. 1. In the present preferred embodiment, a semiconductor element included in the semiconductor device is assumed to be an IGBT. However, the semiconductor element only needs to be a trench-gate semiconductor element and may be, for example, a metal-oxide-semiconductor field-effect transistor (MOSFET).

FIG. 1 illustrates the main part and its periphery of the semiconductor device according to the first preferred embodiment, and specifically illustrates an end of an active region of the semiconductor device and a termination region outside the end portion. The active region is a region where a cell of the semiconductor element is disposed and the main current flows. The termination region is a region that is provided to surround the active region and where a withstand voltage holding structure, gate wiring for controlling the semiconductor element in the active region, and other components are disposed. FIG. 1 illustrates a gate wiring region 100 as the termination region and a cell region 200 as the active region.

The semiconductor device according to the first preferred embodiment is formed using a semiconductor substrate on which an n-type drift layer 11 is formed. The upper main surface of the semiconductor substrate in each FIGS. 2 to 4 is defined as an “upper surface”, and the lower main surface is defined as a “lower surface”. That is, FIG. 1 illustrates the configuration of the upper surface of the semiconductor device.

The material of the semiconductor substrate may be silicon or a wide bandgap semiconductor such as silicon carbide (SiC). A semiconductor device formed using a wide bandgap semiconductor is superior to a conventional semiconductor device using silicon in operating at high voltage, larger current, and higher temperature. Examples of the wide bandgap semiconductor include gallium nitride (GaN)-based materials and diamond, in addition to silicon carbide.

A p-type collector layer 12 is formed in a surface portion on the lower surface side of the semiconductor substrate, that is, on the lower side of the n-type drift layer 11. On the lower surface of the semiconductor substrate, a collector electrode 13 connected to the p-type collector layer 12 is formed. The p-type collector layer 12 and the collector electrode 13 are formed throughout the gate wiring region 100 and cell region 200.

In the cell region 200, a p-type base layer 14 is formed in a surface portion on the upper surface side of the semiconductor substrate, that is, on the upper side of the n-type drift layer 11. In the surface portion of the p-type base layer 14, an n⁺-type source layer 5 and a p⁺-type contact layer 6 are selectively formed. Conversely, the n⁺-type source layer 5 and the p⁺-type contact layer 6 are disposed in the surface portion of the semiconductor substrate, and the p-type base layer 14 is disposed below the n⁺-type source layer 5 and the p⁺-type contact layer 6.

A plurality of trenches extending in the first direction are formed on the upper surface of the semiconductor substrate. The trench is in contact with the n⁺-type source layer 5 and the p-type base layer 14 and reaches the n-type drift layer 11 under the p-type base layer 14. On the inner surface of the trench, a trench-gate insulating film 9 is formed, and on the trench-gate insulating film 9, a first active trench gate 1 is formed to embed the trench.

The first active trench gate 1 extends in the first direction, and the p-type base layer 14, the n⁺-type source layer 5, and the p⁺-type contact layer 6 are disposed between the first active trench gates 1. The first active trench gate 1 faces the n⁺-type source layer 5 and the p-type base layer 14 via the trench-gate insulating film 9. The end of the first active trench gate 1 is disposed in the gate wiring region 100.

On the upper surface of the semiconductor substrate, an interlayer insulating film 10 is formed. The gate wiring electrode 2 is formed on the interlayer insulating film 10 of the gate wiring region 100. The gate wiring electrode 2 is connected to a gate pad (not illustrated) to which a gate drive signal is input. The gate wiring electrode 2 is connected to the first active trench gate 1 through a contact hole formed in the interlayer insulating film 10. A first conductive portion 3 is a contact portion between the gate wiring electrode 2 and the first active trench gate 1. The first active trench gate 1 includes a portion that is wider than other portions in the gate wiring region 100, and the first conductive portion 3 is disposed on the wider portion.

On the upper surface of the semiconductor substrate in the gate wiring region 100, a trench extending in the second direction that intersects the first direction is formed. On the inner surface of the trench, a trench-gate insulating film 9 is formed, and on the trench-gate insulating film 9, a second active trench gate 4 is formed to embed the trench.

The second active trench gate 4 extends in the second direction and connects the adjacent first active trench gates 1. A connection portion between the first active trench gate 1 and the second active trench gate 4 is T-shaped in plan view. The second active trench gate 4 is disposed below the gate wiring electrode 2, specifically, between the first conductive portion 3 and the end of the gate wiring electrode 2.

On the interlayer insulating film 10 in the cell region 200, an emitter electrode 7 is formed. The emitter electrode 7 is connected to the n⁺-type source layer 5 and the p⁺-type contact layer 6 through a contact hole formed in the interlayer insulating film 10. A second conductive portion 8 is a contact portion between the emitter electrode 7 and the n⁺-type source layer 5 and the p⁺-type contact layer 6.

According to the semiconductor device of the first preferred embodiment, since the adjacent first active trench gates 1 are connected by the second active trench gate 4, for example, even if a void occurs in the first conductive portion 3 and a connection failure occurs between some of the first active trench gates 1 and the gate wiring electrode 2, the first active trench gates 1 insulated from the gate wiring electrodes 2 is not generated. In addition, since the connection portion between the first active trench gate 1 and the second active trench gate 4 is T-shaped, there is also an advantage that the trench is suppressed from becoming locally deeper at the connection portion between the first active trench gate 1 and the second active trench gate 4, and the embeddability of the gate electrode is less likely to deteriorate at the connection. Moreover, since the second active trench gate 4 is disposed in the gate wiring region 100 (below the gate wiring electrode 2), the effective area of the semiconductor element is prevented from becoming narrower by providing the second active trench gate 4.

### Second Preferred Embodiment

FIG. 5 is a plan view illustrating a semiconductor device according to a second preferred embodiment. In FIG. 5, components the same as or corresponding to those in FIGS. 1 to 4 are denoted by the same reference numerals as those in FIGS. 1 to 4, and therefore, their descriptions are omitted.

In the semiconductor device according to the second preferred embodiment, the second active trench gate 4 is disposed at the end of the first active trench gate 1. That is, the second active trench gate 4 connects the ends of the adjacent first active trench gates 1. In this case as well, a connection portion between the first active trench gate 1 and the second active trench gate 4 is T-shaped in plan view.

According to the semiconductor device of the second preferred embodiment, the number of T-shaped connection portions between the first active trench gates 1 and the second active trench gate 4 is smaller than that in the first preferred embodiment. An electric field concentrates at the corner of the T-shaped connection portion, and the concentration of electrolysis causes gate leakage current. Therefore, reducing the number of T-shaped connection portions has the effect of suppressing gate leakage current.

### Third Preferred Embodiment

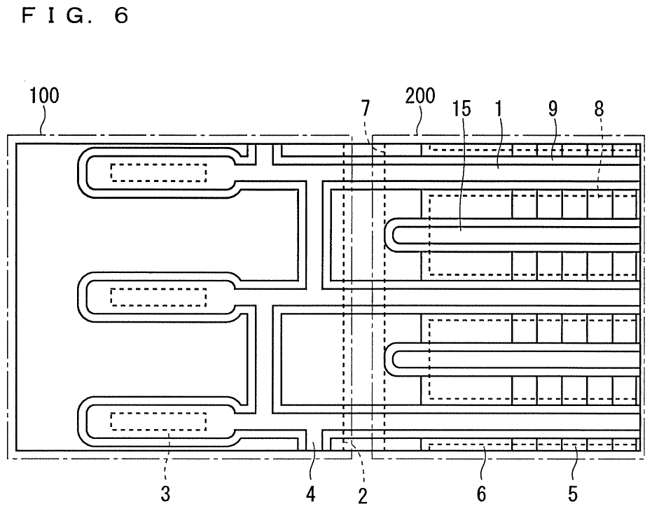

FIG. 6 is a plan view of a semiconductor device according to a third preferred embodiment. In FIG. 6 as well, components the same as or corresponding to those in FIGS. 1 to 4 are denoted by the same reference numerals as those in FIGS. 1 to 4, their descriptions are omitted.

In the semiconductor device according to the third preferred embodiment, the first active trench gates 1 and the dummy trench gates 15 are alternately arranged in the second direction on the upper surface of the semiconductor substrate. Similar to the first active trench gate 1, the dummy trench gate 15 is embedded in a trench extending in the first direction and faces the n⁺-type source layer 5 and the p-type base layer 14 via the trench-gate insulating film 9. However, the dummy trench gate 15 is connected not to the gate wiring electrode 2 but to the emitter electrode 7. Therefore, in the third preferred embodiment, as illustrated in FIG. 6, the second conductive portion 8 is formed to partially overlap the dummy trench gate 15. The end of the dummy trench gate 15 may not reach the gate wiring region 100.

The second active trench gate 4 extending in the second direction connects the first active trench gates 1 adjacent to each other with the dummy trench gate 15 interposed therebetween. A connection portion between the first active trench gate 1 and the second active trench gate 4 is T-shaped in plan view. The position of the second active trench gate 4 may be on the side closer to the cell region 200 than the first conductive portion 3 as in the first preferred embodiment, or may be at the end of the first active trench gate 1 as in the second preferred embodiment.

According to the semiconductor device of the third preferred embodiment, in addition to the effect similar to that of the first or second preferred embodiment, reducing the number of first active trench gates 1 has the effect of reducing gate leakage current generated when the gate drive signal is input.

### Fourth Preferred Embodiment

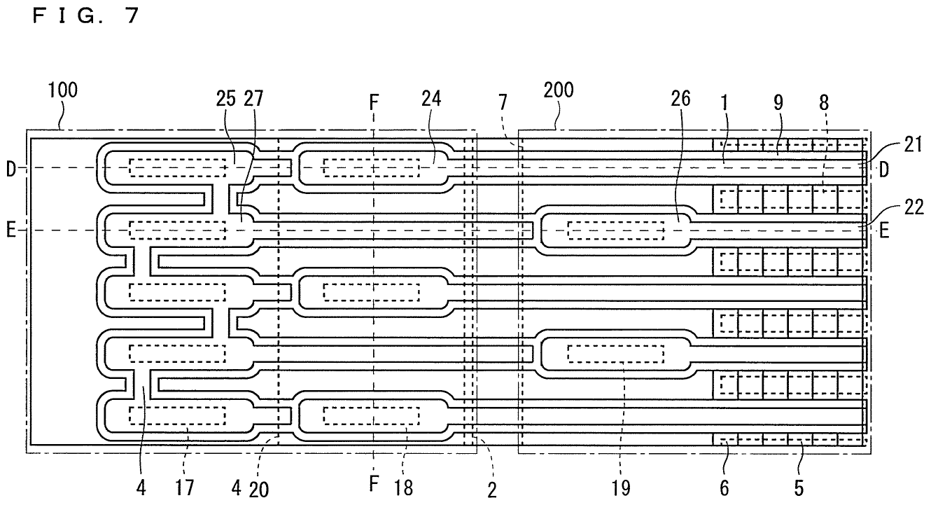

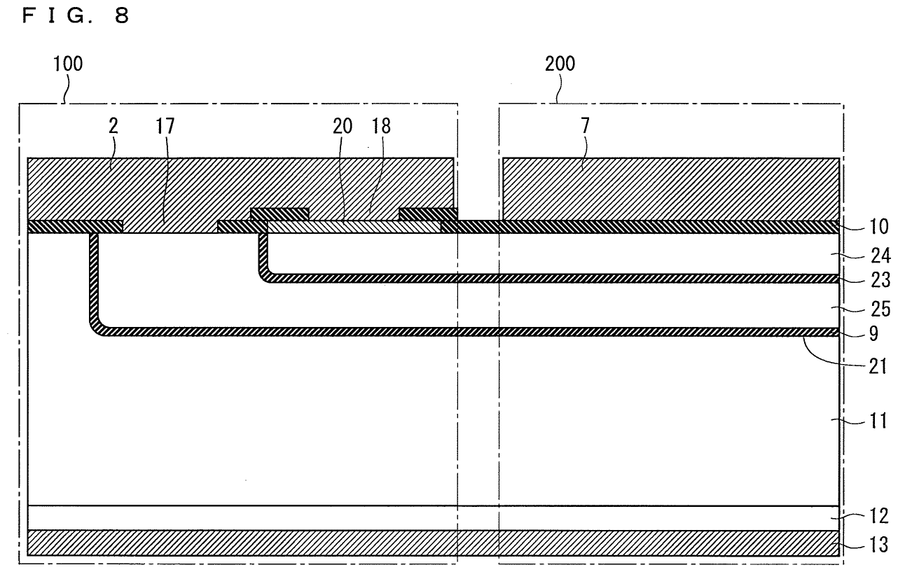

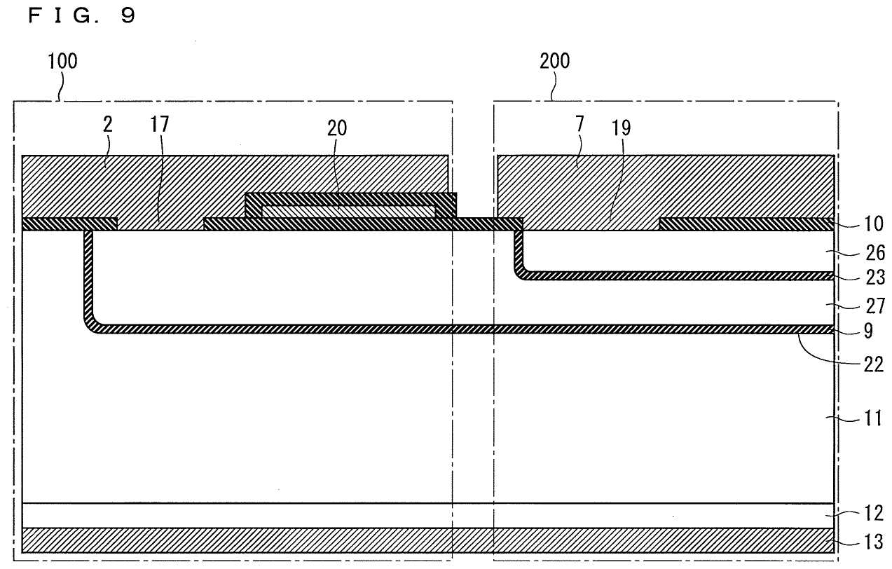

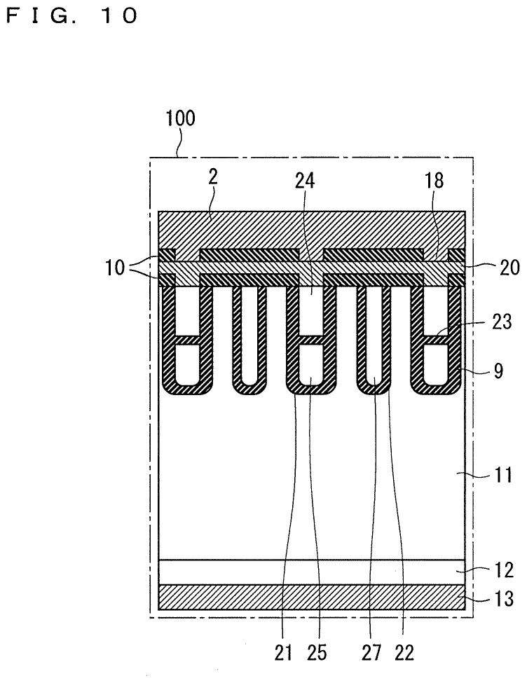

FIGS. 7 to 10 are diagrams illustrating a configuration of a semiconductor device according to a fourth preferred embodiment. FIG. 7 is a plan view of the semiconductor device. FIG. 8 is a cross-sectional view taken along line D-D in FIG. 7. FIG. 9 is a cross-sectional view taken along line E-E in FIG. 7. FIG. 10 is a cross-sectional view taken along line F-F in FIG. 7.

On the upper surface of the semiconductor substrate, first trenches 21 and second trenches 22 extending in the first direction are alternately arranged in the second direction.

On the inner surface (bottom surface and side surface) of the first trench 21, the trench-gate insulating film 9 is formed, and on the trench-gate insulating film 9, a first lower electrode 25 as a first active trench gate is disposed. Moreover, in the first trench 21, a first upper electrode 24 is disposed above the first lower electrode 25 via the electrode isolation insulating film 23. That is, the first lower electrode 25 is disposed in the lower portion of the first trench 21, and the first upper electrode 24 is disposed in the upper portion of the first trench 21. However, as illustrated in FIG. 8, the first lower electrode 25 extends further to the outer side in the gate wiring region 100 than the first upper electrode 24, and the first lower electrode 25 is embedded throughout the first trench 21 in the portion extending beyond the first upper electrode 24. The first lower electrode 25 is connected to the gate wiring electrode 2 through a contact hole, formed in the interlayer insulating film 10, in the portion extending beyond the first upper electrode 24. A third conductive portion 17 is a contact portion between the gate wiring electrode 2 and the first active trench gate (the first lower electrode 25 and a second lower electrode 27 to be described later). In the first trench 21, the third conductive portion 17 is a contact portion between the gate wiring electrode 2 and the first lower electrode 25. The first lower electrode 25 includes a portion, which is wider than the other portions, where the third conductive portion 17 is disposed.

On interlayer insulating film 10 of gate wiring region 100, electrode connection wiring 20 extending in the second direction is formed. The electrode connection wiring 20 is connected to the first upper electrode 24 through a contact hole formed in the interlayer insulating film 10. The first upper electrode 24 includes a portion that is wider than other portions at a contact portion with the electrode connection wiring 20.

As illustrated in FIG. 10, the electrode connection wiring 20 extends in the second direction to cross over the first trench 21 and the second trench 22. The emitter electrode 7 is connected to the electrode connection wiring 20 through a contact hole formed in the interlayer insulating film 10 covering the electrode connection wiring 20. A fourth conductive portion 18 is a contact portion between the emitter electrode 7 and the electrode connection wiring 20. As described above, the electrode connection wiring 20 connects the first upper electrodes 24 to each other and also connects a plurality of first upper electrodes 24 to the emitter electrode 7.

On the inner surface (bottom surface and side surface) of the second trench 22, the trench-gate insulating film 9 is formed, and on the trench-gate insulating film 9, a second lower electrode 27 as a first active trench gate is disposed. Moreover, in the second trench 22, a second upper electrode 26 is disposed above the second lower electrode 27 via the electrode isolation insulating film 23. That is, the second lower electrode 27 is disposed in the lower portion of the second trench 22, and the second upper electrode 26 is disposed in the upper portion of the second trench 22. However, as illustrated in FIG. 9, the second lower electrode 27 extends further to the outer side in the gate wiring region 100 than the second upper electrode 26, and the second lower electrode 27 is embedded throughout the second trench 22 in the portion extending beyond the second upper electrode 26. The second lower electrode 27 is connected to the gate wiring electrode 2 through a contact hole, formed in the interlayer insulating film 10, in the portion extending beyond the second upper electrode 26. In the second trench 22, the third conductive portion 17 is a contact portion between the gate wiring electrode 2 and the second lower electrode 27. The second lower electrode 27 includes a portion, which is wider than other portions, where the third conductive portion 17 is disposed.

As illustrated in FIG. 10, the electrode connection wiring 20 crosses over the second lower electrode 27 of the second trenches 22, but the electrode connection wiring 20 and the second lower electrode 27 are insulated from each other by the interlayer insulating film 10. Therefore, the electrode connection wiring 20 can connect the first upper electrodes 24 of the first trenches 21 across the second lower electrodes 27 of the second trenches 22.

The second upper electrode 26 is connected to the emitter electrode 7 through a contact hole formed in the interlayer insulating film 10 at the end of the cell region 200. Therefore, the end of the second upper electrode 26 may not reach the gate wiring region 100. The fifth conductive portion 19 is a contact portion between the emitter electrode 7 and the second upper electrode 26. The second upper electrode 26 includes a portion, which is wider than other portions, where the fifth conductive portion 19 is disposed.

As illustrated in FIG. 7, the second active trench gate 4 extending in the second direction connects the first lower electrode 25 and the second lower electrode 27 adjacent to each other. A connection portion between the first active trench gate 1 and the first lower electrode 25 and a connection portion between the first active trench gate 1 and the second lower electrode 27 are T-shaped in plan view. The position of the second active trench gate 4 may be on the side closer to the cell region 200 than the third conductive portion 17, or may be at the ends of the first lower electrode 25 and the second lower electrode 27.

According to the semiconductor device of the fourth preferred embodiment, since the first lower electrode 25 and the second lower electrode 27 are connected by the second active trench gate 4, even if disconnection occurs in a part of the third conductive portion 17, conduction between the electrode connection wiring 20 and the first lower electrode 25 and the second lower electrode 27 can be maintained. In addition, since the first upper electrode 24 are connected to each other by the electrode connection wiring 20, even if disconnection occurs in a part of the fourth conductive portion 18, conduction between the electrode connection wiring 20 and the first upper electrode 24 can be maintained.

Note that it is possible to freely combine each of the preferred embodiments and to appropriately modify or omit each of the preferred embodiments.

### APPENDIX

Hereinafter, various aspects of the present disclosure will be collectively described as appendixes.

### Appendix 1

A semiconductor device including:
a semiconductor substrate;
an emitter electrode and a gate wiring electrode provided on an upper surface of the semiconductor substrate;
a source layer of a first conductivity type disposed on a surface portion on the upper surface side of the semiconductor substrate and connected to the emitter electrode;
a base layer of a second conductivity type disposed below the source layer;
a collector electrode provided on a lower surface of the semiconductor substrate;
a plurality of first active trench gates extending in a first direction and facing the source layer and the base layer via a trench-gate insulating film; and
a second active trench gate extending in a second direction that intersects the first direction and connecting the adjacent first active trench gates to each other,
wherein each of a plurality of the first active trench gates includes a portion that is wider than other portions,
the gate wiring electrode extends in the second direction and is connected to the wider portion in each of a plurality of the first active trench gates,
the second active trench gate is disposed below the gate wiring electrode, and
a connection portion between the first active trench gate and the second active trench gate is T-shaped in plan view.

### Appendix 2

The semiconductor device according to Appendix 1, wherein the second active trench gate is connected to an end of the first active trench gate.

### Appendix 3

The semiconductor device according to Appendix 1 or 2, wherein a dummy trench gate extending in the first direction and connected to the emitter electrode is provided between the first active trench gates.

### Appendix 4

The semiconductor device according to Appendix 1 or 2, further including:
a first trench that extends in the first direction and in which a first lower electrode serving as the first active trench gate and a first upper electrode are embedded, the first upper electrode being provided above the first lower electrode via an electrode isolation insulating film; and
a second trench that extends in the first direction and in which a second lower electrode serving as the first active trench gate and a second upper electrode are embedded, the second upper electrode being provided above the second lower electrode via the electrode isolation insulating film,
wherein the first trenches and the second trenches are provided alternately in the second direction,
the semiconductor device further includes electrode connection wiring that extends in the second direction and connects, across the second trench, the first upper electrodes adjacent to each other with the second trench interposed between the first upper electrodes, and
the electrode connection wiring is connected to the gate wiring electrode.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
an emitter electrode and a gate wiring electrode provided on an upper surface of the semiconductor substrate;
a source layer of a first conductivity type disposed on a surface portion on the upper surface side of the semiconductor substrate and connected to the emitter electrode;
a base layer of a second conductivity type disposed below the source layer;
a collector electrode provided on a lower surface of the semiconductor substrate;
a plurality of first active trench gates extending in a first direction and facing the source layer and the base layer via a trench-gate insulating film; and
a second active trench gate extending in a second direction that intersects the first direction and connecting the adjacent first active trench gates to each other,
wherein each of a plurality of the first active trench gates includes a portion that is wider than other portions,
the gate wiring electrode extends in the second direction and is connected to the wider portion in each of a plurality of the first active trench gates,
the second active trench gate is disposed below the gate wiring electrode, and
a connection portion between the first active trench gate and the second active trench gate is T-shaped in plan view.

2. The semiconductor device according to claim 1, wherein the second active trench gate is connected to an end of the first active trench gate.

3. The semiconductor device according to claim 1, wherein a dummy trench gate extending in the first direction and connected to the emitter electrode is provided between the first active trench gates.

4. The semiconductor device according to claim 2, wherein a dummy trench gate extending in the first direction and connected to the emitter electrode is provided between the first active trench gates.

5. The semiconductor device according to claim 1, further comprising:
a first trench that extends in the first direction and in which a first lower electrode serving as the first active trench gate and a first upper electrode are embedded, the first upper electrode being provided above the first lower electrode via an electrode isolation insulating film; and
a second trench that extends in the first direction and in which a second lower electrode serving as the first active trench gate and a second upper electrode are embedded, the second upper electrode being provided above the second lower electrode via the electrode isolation insulating film,
wherein the first trenches and the second trenches are provided alternately in the second direction,
the semiconductor device further comprises electrode connection wiring that extends in the second direction and connects, across the second trench, the first upper electrodes adjacent to each other with the second trench interposed between the first upper electrodes, and
the electrode connection wiring is connected to the gate wiring electrode.

6. The semiconductor device according to claim 2, further comprising:
a first trench that extends in the first direction and in which a first lower electrode serving as the first active trench gate and a first upper electrode are embedded, the first upper electrode being provided above the first lower electrode via an electrode isolation insulating film; and
a second trench that extends in the first direction and in which a second lower electrode serving as the first active trench gate and a second upper electrode are embedded, the second upper electrode being provided above the second lower electrode via the electrode isolation insulating film,
wherein the first trenches and the second trenches are provided alternately in the second direction,
the semiconductor device further comprises electrode connection wiring that extends in the second direction and connects, across the second trench, the first upper electrodes adjacent to each other with the second trench interposed between the first upper electrodes, and
the electrode connection wiring is connected to the gate wiring electrode.
